(19) United States
(12) Patent Application Publication
(10) Pub. No.: US 2014/0197026 A1
(43) Pub. Date: Jul. 17, 2014

(54) SPUTTERING APPARATUS AND METHOD FOR FORMING A TRANSMISSIVE CONDUCTIVE LAYER OF A LIGHT EMITTING DEVICE

(71) Applicants: Young Chul Shin, Seoul (KR); Gi Bum Kim, Hwasung-si (KR); Won Goo Hur, Incheon (KR)

(72) Inventors: Young Chul Shin, Seoul (KR); Gi Bum Kim, Hwasung-si (KR); Won Goo Hur, Incheon (KR)

(73) Assignee: SAMSUNG ELECTRONICS CO., LTD., Suwon-si (KR)

(21) Appl. No.: 14/239,109

(22) PCT Filed: Aug. 17, 2011
(86) PCT No.: PCT/KR2011/006014

§ 371 Date: Feb. 14, 2014

(51) Int. Cl. H01J 37/34

(52) U.S. Cl. CPC H01J 37/3411
USPC 204/192.29; 204/298.11

(57) ABSTRACT

There is provided a method for manufacturing a nitride semiconductor light emitting device, including: forming a light emitting structure including first and second conductive nitride semiconductor layers on a substrate and an active layer formed therebetween; forming the first conductive nitride semiconductor layer, the active layer, and the second conductive nitride semiconductor layer in sequence; forming a first electrode connected to the first conductive nitride semiconductor layer; forming a photo-resist layer on the second conductive nitride semiconductor layer so as to expose a portion of the semiconductor layer; and removing the photo-resist layer after a reflective metal layer and a barrier metal layer serving as a second electrode structure are successively formed on the second conductive nitride semiconductor layer exposed by the photo-resist layer.

### TECHNICAL FIELD

The present disclosure relates to a sputtering apparatus and method for forming a transmissive conductive layer of a light emitting device, and more particularly, to a novel apparatus capable of preventing a deterioration of ohmic characteristics due to degradation of a p-type semiconductor, that may be generated in the case of forming a transmissive conductive layer on a light emitting device using a sputtering method in order to improve productivity, and a sputtering method using the same.

### BACKGROUND ART

A light emitting device refers to a device that converts energy generated due to the recombination of electrons and holes using the characteristics of a p-n junction structure of a semiconductor device into light and emits the light.

That is, when a forward direction voltage is applied to a semiconductor formed of certain elements, electrons and holes move through a junction between a positive electrode and a negative electrode and recombine with one another to thereby have energy lower than that of a case in which the electrons and holes are separated from one another. Due to a difference in energy generated at this time, light may be emitted outwardly.

Therefore, a basic shape of a light emitting device may be a stacked structure including an n-type semiconductor 20 and a p-type semiconductor 40 formed on a substrate 10, and a multiple quantum well (MQW) layer 30 formed between the n-type semiconductor 20 and the p-type semiconductor 40 (in the respective semiconductors, GaN may be provided by way of an example), as exemplified as a MESA structure in FIG. 1. In a case in which a current is supplied to the stacked structure, electrons and holes move towards the multiple quantum well (MQW) layer and recombine with one another to generate light energy.

In this case, in order to supply a current to the stacked structure, electrodes may be formed on the p-type semiconductor 40 (more precisely, p⁺-GaN (50)) and the n-type semiconductor 20 so as to supply the current thereto. In particular, it may be necessary to form an electrode on the p-type semiconductor with a broad contact area in terms of characteristics of the semiconductor. Further, in order to enable generated light to serve as a light source, a high degree of light extraction efficiency may be required, such that light may be emitted toward an observer of a light emitting device without loss. Therefore, the electrode may be formed of a transmissive conductive layer 60 such as a transparent conductive oxide (TCO) layer.

In general, a majority of processes of forming the transmissive conductive layer 60 may be formed by a deposition method, and an electron beam deposition method may be the most widely used as a method of forming the transmissive conductive layer on a p-type semiconductor 40 in which doping characteristics are sensitively varied, more particularly, on a surface of a p⁺-type semiconductor formed to enable the p-type semiconductor and an electrode to be in ohmic-contact with each other.

However, the electron beam deposition method, a batch type method of evaporating a material to be deposited and depositing the material, may have defects such as lowered stability of a process of forming a transmissive conductive layer, a reduction in productivity, and the like. An alternative for forming a layer with high process stability and productivity may be a sputtering method, by way of example. However, in the sputtering method, a semiconductor layer such as p⁺-GaN or the like may be damaged due to plasma formed at the time of sputtering and accordingly, as illustrated in FIG. 2, a deterioration of ohmic-characteristics may be caused therein as compared to the electron beam deposition method, whereby the application of the sputtering method has been defective.

### DISCLOSURE

### Technical Problem

An aspect of the present disclosure provides a sputtering apparatus allowing for implementation of a method for enabling a semiconductor layer and the transmissive conductive layer to be in ohmic-contact with each other at the time of forming the transmissive conductive layer on a light emitting device.

An aspect of the present disclosure also provides a novel method for enabling a semiconductor layer and the transmissive conductive layer to be in good ohmic-contact with each other at the time of forming the transmissive conductive layer on a light emitting device by a sputtering method.

### Technical Solution

According to an aspect of the present disclosure, there is provided a sputtering apparatus for forming a transmissive conductive layer of a light emitting device, the sputtering apparatus including: a chamber; a target receiving unit disposed on one inner wall of the chamber; a substrate receiving unit formed to be opposed to the target receiving unit; and a filter formed of two or more layers of metal nets between the target receiving unit and the substrate receiving unit.

At least one layer of the filter formed of two or more layers of metal nets may be used as a grounding electrode.

The filter formed of two or more layers of metal nets may have perforations in a mesh or stripe pattern. The filter formed of two or more layers of metal nets may have open portions thereof disposed alternately with each other.

In the filter formed of two or more layers of metal nets, a width of a metal part may be 10 μm to 10 mm and a width of a perforation may be 10 μm to 10 mm, such that deterioration of a p-type semiconductor serving as a substrate, due to plasma and atoms discharged during sputtering, may be effectively prevented.

In addition, an interval between the filter and a substrate received in the substrate receiving unit may be 10 to 500 mm.

According to another aspect of the present disclosure, there is provided a sputtering method for forming a transmissive conductive layer of a light emitting device, the sputtering method including: preparing a substrate and a target; and depositing elements of the target on the substrate through sputtering, wherein during the sputtering, a filter formed of two or more layers of metal nets is provided between the target and the substrate, and at least one layer of the filter is used as a grounding electrode.

In order to further promote an improvement in productivity, an advantageous effect of the sputtering method, the sputtering may include a first sputtering process of performing sputtering at a deposition rate of 0.1 to 200 Å/sec. until a thickness of a transmissive conductive layer is 10 to 1000 Å, and a second sputtering process of performing sputtering at a deposition rate of 1 to 2000 Å/sec. to a final thickness of the transmissive conductive layer after the thickness thereof reaches 10 to 1000 Å.

The filter formed of two or more layers of metal nets may have gradations in a mesh or stripe pattern. The filter formed of two or more layers of metal nets may have open portions thereof disposed alternately with each other.

### Advantageous Effects

According to exemplary embodiments of the present disclosure, when particles of a material for a transmissive conductive layer, discharged from a target arrive at a p-type semiconductor, a substrate, a deterioration of the p-type semiconductor may be prevented by maximally reducing energy of the particles and enabling plasma generated during sputtering to have no influence on a portion adjacent to the p-type semiconductor. As a result, a light emitting device may be manufactured with high processing stability and productivity.

### DESCRIPTION OF DRAWINGS

FIG. 1 is a cross-sectional view schematically illustrating a shape of the light emitting device having a MESA structure.

FIG. 2 is a graph illustrating a phenomenon in which ohmic-contact characteristics are varied when a transmissive conductive layer is formed by a sputtering method and when a transmissive conductive layer is formed by an electron beam method.

FIG. 3 is a cross-sectional view illustrating a shape of a sputtering apparatus according to the related art.

FIG. 4 is a cross-sectional view illustrating a shape of a sputtering apparatus according to an exemplary embodiment of the present disclosure.

FIG. 5 is plan views illustrating shapes of a metal net configuring a filter.

FIG. 6 is a schematic description view illustrating a shape in which perforations of the metal nets configuring the filter intersect with each other.

FIG. 7 is a graph illustrating a comparison result of ohmic characteristics of indium tin oxide (ITO) layers formed by an inventive example according to the present disclosure and formed by a related art example according to the related art.

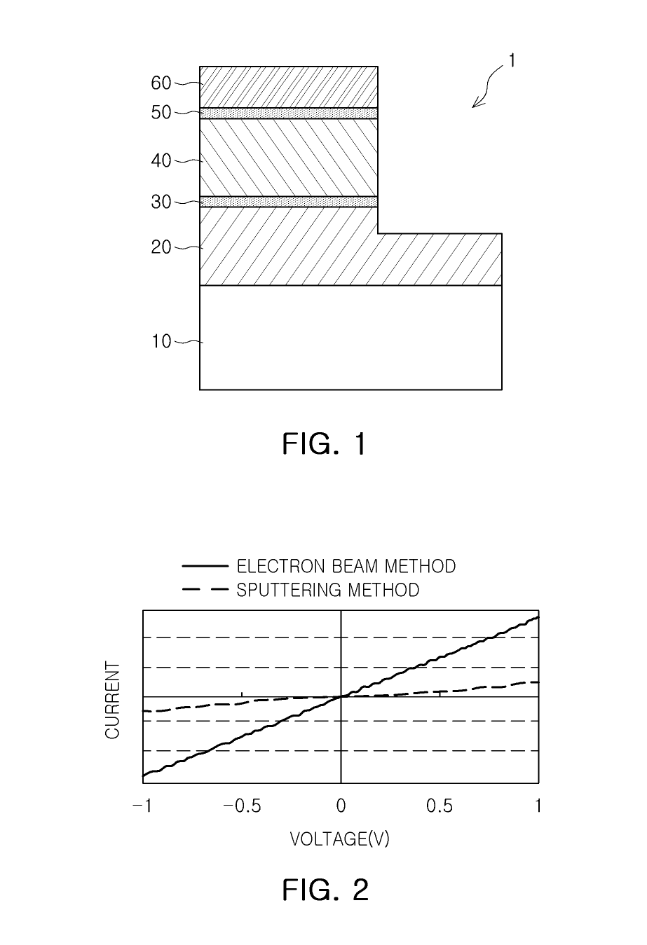

### BEST MODE

Hereinafter, exemplary embodiments of the present disclosure will be described with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity.

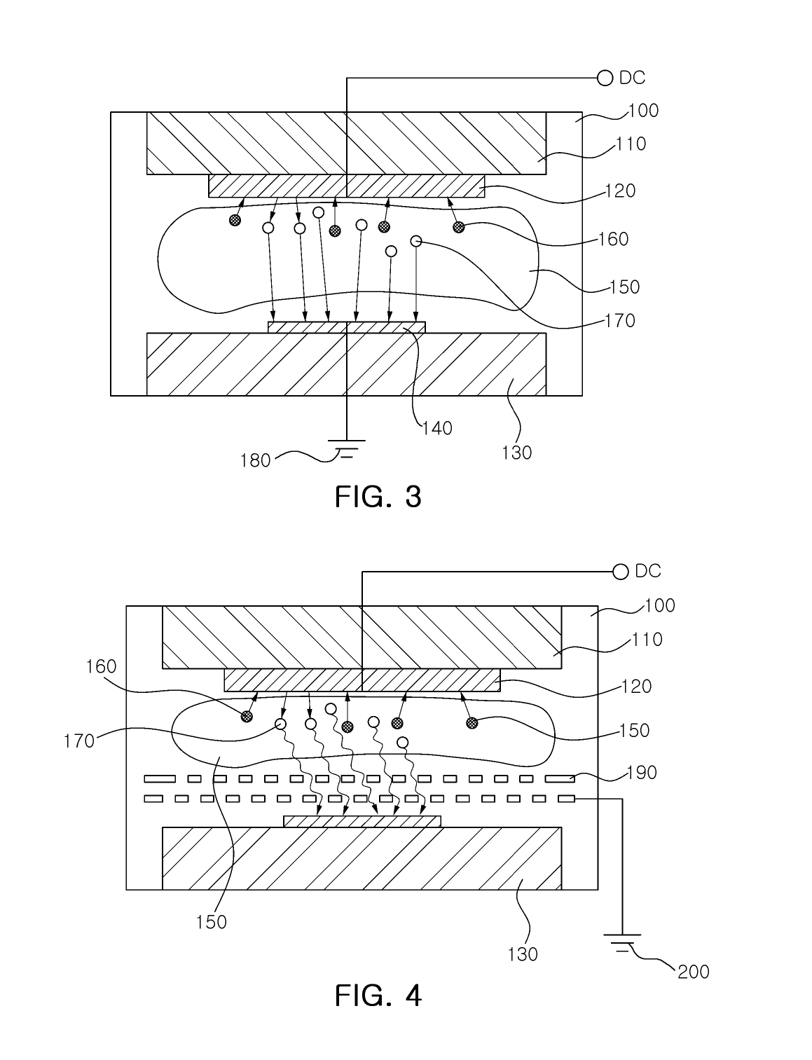

FIG. 3 schematically illustrates a sputtering scheme according to the related art. As can be seen in the drawings, in a sputtering apparatus according to the related art, a target 120 received in a target receiving unit 110 may be provided as a negative electrode and a substrate 140 received in a substrate receiving unit 130 may be grounded to thereby generate an electric field. Plasma 150 may be formed due to the generated electric field, and elements 170 forming the target 120 may be discharged from the target due to energy generated at the time of collision between Ar⁺ 160 contained in the plasma and the target 120. The discharged elements 170 may be adhered to the substrate 140 disposed to be opposed to the target to thereby form a layer.

The scheme described above may have high processing stability and allow for the easy exchange of materials, thereby leading to high productivity, as compared to an electron beam method according to the related art.

However, in order to separate elements (atoms) 170 from the target, the formation of Ar⁺ plasma may be necessarily. The plasma may be formed between the target 120 and a grounding electrode 180 and may have a high level of energy sufficient to ionize neutral Ar gas in a plasma state.

However, according to the inventors' research results in the present disclosure, high energy of plasma may be adjacent to a substrate and have an effect thereon due to characteristics of the sputtering apparatus generating plasma, whereby an energy level of a p-type semiconductor may be increased and as a result, it may be difficult to obtain good ohmic-contact between the p-type semiconductor and a transmissive conductive layer formed thereon.

The inventors also found the fact that atoms discharged from the target due to the collision of Ar⁺ plasma ions having high energy may also have high energy, and in a case in which particles having such high energy collide with the p-type semiconductor to be adhered thereto, deterioration of the p-type semiconductor may be caused to thereby hinder good ohmic-contact from being obtained.

The present disclosure may be obtained according to two measures acquired on the basis of the point of view, and two measures are simply described as below.

First, shielding the substrate from a plasma generation region may be required. That is, a region in which the plasma is generated and the substrate may be separated from each other, whereby it may be necessary to prevent an increase in an energy level of the p-type semiconductor, the substrate, due to the energy of plasma.

Next, it may be necessary for atoms discharged from the target to collide with the substrate while having reduced energy to thereby prevent deterioration of the substrate.

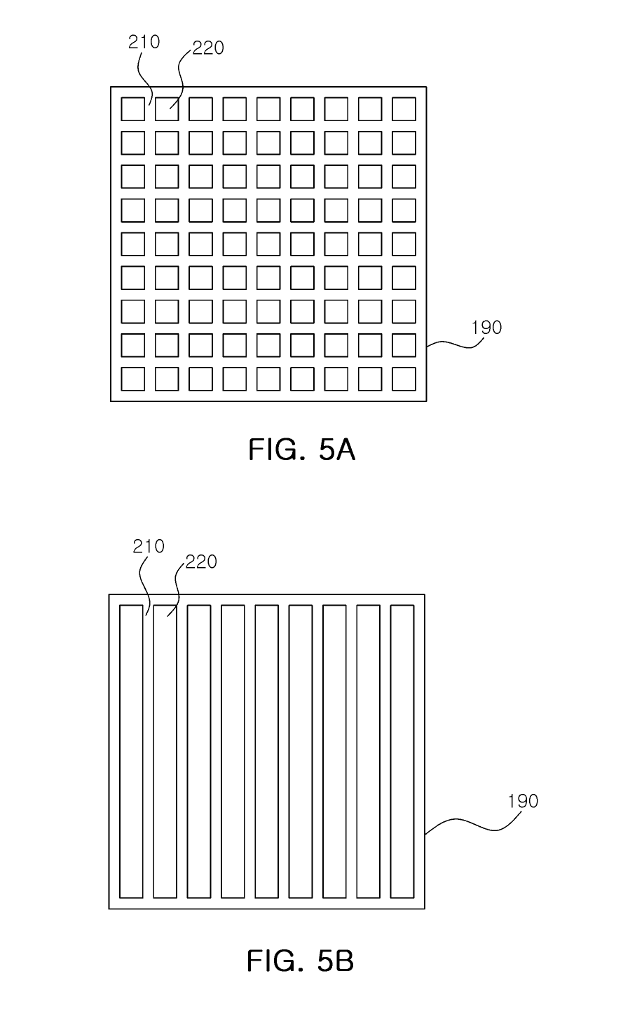

FIG. 4 is a schematic view illustrating a sputtering apparatus depending on a unique solution of the present disclosure. As can be seen in FIG. 4, a sputtering apparatus according to an exemplary embodiment of the present disclosure may include a chamber 100 for generating plasma, a target receiving unit 110 disposed on one inner wall of the chamber 100 and receiving a target 120 therein, a substrate receiving unit 130 disposed to be opposed to the target receiving unit 110 and receiving a substrate 140 therein, and two or more layers of a filter 190 having open portions between the target receiving unit 110 and the substrate receiving unit 130. The target received in the target receiving unit may be a negative electrode. In addition, as illustrated in FIG. 5, the filter 190 may be formed of metal nets having gradations in a mesh pattern (a) or in a stripe pattern (b) and at least one of the two or more layers of the filter may be provided as a grounding electrode 200. In this case, the mesh patterns of the metal net 190 may not necessarily have a quadrangular shape, but may be variously formed such as having a circular shape, an oval shape, a polygonal shape, or the like.

This will be described in detail as below. As described above, in a case in which the plasma 150 is in direct contact with a p-type semiconductor, the substrate 140, an energy level of the p-type semiconductor may be increased, thereby leading to an inability to obtain good ohmic-contact between the transmissive conductive layer and the p-type semiconductor. Therefore, the filter 190 according to the exemplary embodiment of the present disclosure may be disposed between the target 120 as a negative electrode and the substrate 140, and at least one layer of the filter 190 may be provided as the grounding electrode 200, such that a region of the plasma 150 may be confined to a space between the substrate and the filter.

In this case, direct contact between the plasma and the substrate (p-type semiconductor) may be prevented, such that good ohmic-contact may be obtained.

In addition, in a case in which the filter is configured of a single layer, atoms discharged from the target may conflict with the substrate, while having high energy. Thus, it may be necessary to prevent atoms having a high velocity (That is, high kinetic energy or a high quantity of motion) from directly conflicting with the substrate by configuring the filter to have two or more layers to thereby lengthen a path to the substrate by as much as possible or allow for a complicated path of atoms, rather than a linear path thereof.

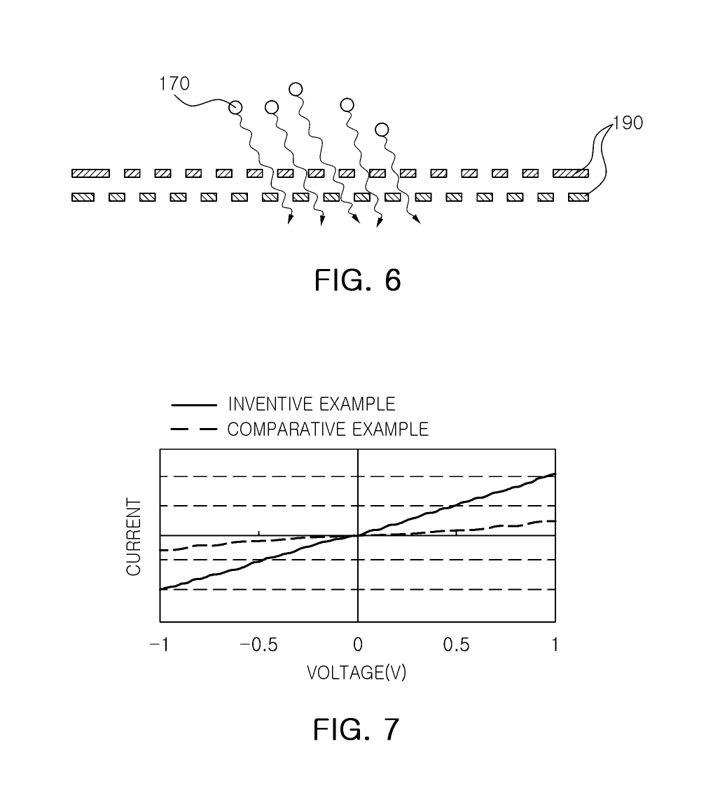

In this case, when viewed in a direction from the target toward the substrate, open regions (that is, regions opened to enable atoms to pass therethrough) between adjacent mesh or stripe patterns of the filter may be disposed alternately as illustrated in FIG. 6, such that the atoms discharged from the target may not reach the substrate via a shortest path and may arrive at the substrate at an angle as diagonal as possible.

In a case in which the number of layers of the filter is increased, ohmic characteristics may be improved, but a ratio of atoms arriving at the substrate may be reduced to thereby result in a lowering of productivity. Thus, the filter may be formed of two layers.

A width of a metal part 210 in the metal net forming the filter may be 10 μm to 10 mm, and a width of a perforation (a non-metal part) 220 may be 10 μm to 10 mm. In a case in which the width of the metal part 210 is extremely small or the width of the perforation 220 is excessively large, the filter may insufficiently control the path of atoms, while in a case in which the width of the metal part 210 is extremely large or the width of the perforation 220 is excessively small, a film forming efficiency of the transmissive conductive layer may be reduced. Due to similar reasons, an interval between the metal nets forming the filter may be 0.1 to 200 mm.

In addition, in the sputtering apparatus, an interval between the filter 190 and the substrate 140 may be 10 to 500 mm. This is because a sufficient interval between the substrate 140 and the filter 190 may be maintained, such that deterioration of ohmic characteristics due to the plasma 150 may be prevented and at the same time, the atoms discharged from the target may be adhered to the substrate 140 with a significantly high efficiency.

Thus, the sputtering apparatus for forming the transmissive conductive layer according to the exemplary embodiment of the present disclosure may include the chamber, the target receiving unit disposed on one inner wall of the chamber, the substrate receiving unit formed to be opposed to the target receiving unit, and the filter formed of two or more layers of metal nets between the target receiving unit and the substrate receiving unit.

As the sputtering apparatus according to the exemplary embodiment of the present disclosure, any type of apparatus may be used and more preferably, a direct current (DC) sputtering apparatus may be used. Among types of DC sputtering apparatus, a DC magnetron sputtering apparatus may preferably be used.

Further, a method for forming the transmissive conductive layer according to an exemplary embodiment of the present disclosure, a method of using the sputtering apparatus described above, may include preparing the substrate and the target; and depositing the elements from the target on the substrate through sputtering, wherein during the sputtering, the filter formed of two or more layers of metal nets may be provided between the target and the substrate, and the filter may be used as a grounding electrode. In this case, when the substrate may be a substrate having a stacked structure in which the p-type semiconductor is a top layer, advantageous effects according to the exemplary embodiments of the present disclosure may be obtained.

In this case, during the sputtering, when atoms are discharged at an excessively rapid velocity, consequently a degree of improvement in ohmic-contact between the substrate and the transmissive conductive layer may be insignificant. Thus, it may be necessary to control a discharging velocity of atoms, in other words, a deposition rate, during the sputtering. That is, the deposition rate of the transmissive conductive layer may be 0.1 to 200 Å/sec. at an initial stage to prevent deterioration of the substrate, and then the transmissive conductive layer may be deposited at an increased deposition rate of 1 to 2000 Å/sec, thereby achieving improvements in productivity.

The sputtering may be entirely undertaken under current application conditions described above, but in such a case, the deposition rate may be relatively low, to thereby degrade productivity. Therefore, in the method according to the exemplary embodiment of the present disclosure, the sputtering may be divided into two sputtering processes to be controlled. That is, one sputtering process may be performed under the conditions described above in order to obtain good ohmic-contact at the initial stage. However, when a thickness of the correspondingly formed transmissive conductive layer becomes 10 to 1000 Å, the already formed transmissive conductive layer may serve as a protective layer and accordingly ohmic characteristics may no longer be deteriorated, unless the transmissive conductive layer is deposited at an extremely high rate. Thus, in the case of the thickness of 10 to 1000 Å, even when another sputtering process is performed at an increased deposition rate, good ohmic-contact characteristics may be obtained between the substrate and the transmissive conductive layer.

Thus, the sputtering may be performed in two separate processes, including a first sputtering process of performing sputtering at a deposition rate of 0.1 to 200 Å/sec. until the thickness of the transmissive conductive layer is 10 to 1000 Å, and a second sputtering process of performing sputtering at a deposition rate of 1 to 2000 Å/sec. to a final thickness of the transmissive conductive layer after the thickness thereof reaches 10 to 1000 Å.

In the apparatus and method described above, although the transmissive conductive layer may be formed on the p-type semiconductor forming the stacked structure of the light emitting device through sputtering by preventing deterioration of the substrate due to the plasma and preventing deterioration of the substrate due to high kinetic energy of atoms discharged from the target, ohmic characteristics between the transmissive conductive layer and the p-type semiconductor may be improved, such that functions of the light emitting device may be further improved.

### Mode for Disclosure

In addition, an exemplary embodiment of the present disclosure has been described depending on a partial example described, but it is important to understand that the scope of the present disclosure is not limited to the example. That is, the scope of the present disclosure may be determined by descriptions of claims attached to the specification and matters reasonably conceived of from the claims, and is not limited to the individual example.

### EXAMPLES

An indium tin oxide (ITO) layer was formed on a surface of a substrate having a p+-type semiconductor formed at a top layer thereof at a deposition rate of 2 Å/sec. by using a sputtering apparatus including a filter formed of two layers of metal nets, a width of a metal part being 1 mm and a width of a perforation being 1 mm, the two layers of metal nets being spaced apart from each other by a distance of 5 mm in such a manner that the metal part of one metal net is disposed above the center of the perforation of the other metal net so as to enable open portions thereof to be disposed alternately, a distance between the two layers of metal nets and the substrate being 200 mm. This case is referred to as the inventive example.

As a related art example as compared to the inventive example, an ITO layer was formed on a surface of a substrate having a p+-type semiconductor formed at a top layer thereof, by using a sputtering apparatus having no metal nets.

FIG. 7 is a graph illustrating a comparison result of ohmic characteristics of ITO layers formed by the inventive example according to the present disclosure and formed by the related art example according to the related art. As can be seen in the graph of FIG. 7, in the ITO layer manufactured according to the related art example, a current was barely increased, even with an increase in voltage. On the other hand, in the ITO layer manufactured according to the inventive example, a current was increased in a linear manner in accordance with an increase in voltage.

Therefore, advantageous effects according to the exemplary embodiments of the present disclosure could be confirmed.

While the present disclosure has been shown and described in connection with the embodiments, it will be apparent to those skilled in the art that modifications and variations can be made without departing from the spirit and scope of the disclosure as defined by the appended claims.

1. A sputtering apparatus for forming a transmissive conductive layer of a light emitting device, comprising:
a chamber;
a target receiving unit disposed on one inner wall of the chamber;
a substrate receiving unit formed to be opposed to the target receiving unit; and
a filter formed of two or more layers of metal nets between the target receiving unit and the substrate receiving unit.

2. The sputtering apparatus of claim 1, wherein at least one layer of the filter formed of two or more layers of metal nets is used as a grounding electrode.

3. The sputtering apparatus of claim 1, wherein the filter formed of two or more layers of metal nets has perforations in a mesh or stripe pattern.

4. The sputtering apparatus of claim 3, wherein the filter formed of two or more layers of metal nets has open portions thereof disposed alternately with each other.

5. The sputtering apparatus of claim 3, wherein in the filter formed of two or more layers of metal nets, a width of a metal part is 10 μm to 10 mm and a width of a perforation is 10 μm to 10 mm.

6. The sputtering apparatus of claim 3, wherein an interval between the filter and a substrate received in the substrate receiving unit is 10 to 500 mm.

7. A sputtering method for forming a transmissive conductive layer of a light emitting device, comprising:
preparing a substrate and a target; and
depositing elements from the target on the substrate by sputtering,
wherein during the sputtering, a filter formed of two or more layers of metal nets is provided between the target and the substrate, and at least one layer of the filter is used as a grounding electrode.

8. The sputtering method of claim 7, wherein the sputtering includes a first sputtering process of performing sputtering at a deposition rate of 0.1 to 200 Å/sec. until a thickness of a transmissive conductive layer is 10 to 1000 Å, and a second sputtering process of performing sputtering at a deposition rate of 1 to 2000 Å/sec. to a final thickness of the transmissive conductive layer after the thickness thereof reaches 10 to 1000 Å.

9. The sputtering method of claim 7, wherein the filter formed of two or more layers of metal nets has perforations in a mesh or stripe pattern.

10. The sputtering method of claim 9, wherein the filter formed of two or more layers of metal nets has open portions thereof disposed alternately with each other.
